(19) United States
(12) Patent Application Publication
(10) Pub. No.: US 2021/0328162 A1
(43) Pub. Date: Oct. 21, 2021

(54) FLEXIBLE ELECTRONIC ELEMENT SUBSTRATE, ORGANIC THIN FILM SOLAR CELL, LAMINATED STRUCTURE AND METHOD FOR MANUFACTURING THE SAME, AND METHOD FOR MANUFACTURING FLEXIBLE ELECTRONIC ELEMENT

(71) Applicants: RIKEN, Wako-shi, Saitama (JP); Mitsui Chemicals, Inc., Minato-ku, Tokyo (JP)

(72) Inventors: Kenjiro FUKUDA, Wako-shi, Saitama (JP); Hiroki KIMURA, Wako-shi, Saitama (JP); Takao SOMEYA, Wako-shi, Saitama (JP); Kenichi FUKUKAWA, Shinagawa-ku, Tokyo (JP); Masaki OKAZAKI, Chiba-shi, Chiba (JP); Tatsuhiro URAKAMI, Ichihara-shi, Chiba (JP)

(73) Assignees: RIKEN, Wako-shi, Saitama (JP); Mitsui Chemicals, Inc., Minato-ku, Tokyo (JP)

(21) Appl. No.: 17/264,993

(22) PCT Filed: Mar. 4, 2019
(86) PCT No.: PCT/JP2019/008427

§ 371 Date: Feb. 1, 2021

(30) Foreign Application Priority Data
Aug. 2, 2018 (JP) 2018-145648

(51) Int. Cl. H01L 51/00; H01L 51/44; C08G 73/10; C08J 5/18; B05D 3/12; B05D 5/06

(52) U.S. Cl. CPC H01L 51/0097; H01L 51/44; C08G 73/10; C08J 5/18; B05D 2505/50; B05D 5/06; B05D 2203/35; B05D 2350/60; B05D 3/12

(57) ABSTRACT

The present invention addresses the problem of providing a flexible electronic element substrate comprising a polyimide layer that has both low ultraviolet transmittance and high visible light transmittance and that is capable of suppressing ultraviolet degradation without any reduction in the performance of an electronic element. In order to solve this problem, the flexible electronic element substrate comprises a polyimide layer that satisfies all of (1) through (3) below: (1) maximum transmittance at a wavelength of 400±5 nm is 70% or higher at a thickness of 5 μm; (2) the b* value in an L*a*b* color system is 5 or less at a thickness of 5 μm; and (3) transmittance of light at a wavelength of 350 nm is 10% or less at a thickness of 5 μm.

### TECHNICAL FIELD

The present invention relates to a substrate for a flexible electronic device, an organic thin film solar cell, a laminated structure and a method for manufacturing the same, and a method for manufacturing a flexible electronic device.

### BACKGROUND ART

In recent years, electronic devices having flexibility (hereinafter also referred to as “flexible electronic devices”) have been receiving attention. In particular, elements composed mainly of organic materials are receiving attention because of their potential for weight reduction and cost reduction. Especially, organic thin film solar cells are expected to be commercialized.

Conventionally, glass substrates have been mainly used as substrates for thin film solar cells. However, the glass substrate is easily cracked and require careful handling, and they have the disadvantage of low flexibility. Therefore, it has been considered to replace the glass substrate with a substrate composed of a flexible resin.

For example, Non-Patent Literature 1 describes a solar cell using a polyethylene terephthalate (PET) film as a substrate. Non-Patent Literature 2 describes a formation of a solar cell element on a parylene film formed by CVD method.

### CITATION LIST

### Non-Patent Literature

### NPL 1

Nature communications, 2012, 3:770

### NPL 2

Nature Energy 2 780-785 (2017)

### SUMMARY OF INVENTION

### Technical Problem

In general, electronic devices are susceptible to ultraviolet light. For example, in thin film solar cells, long-term exposure to ultraviolet light reduces photoelectric conversion efficiency. On the other hand, conventional substrate, such as the glass substrate, the PET film, or the parylene film, has a high transmittance of ultraviolet light. Therefore, it has been examined to laminate a filter (hereinafter also referred to as “UV cut filter”) for absorbing or reflecting ultraviolet light on these substrates. However, when a general UV cut filter is laminated, compared to a case where the UV cut filter is not laminated, a problem, such as decrease in photoelectric conversion efficiency, arises since the UV cut filter shields light having effective wavelength for photoelectric conversion.

The present invention has been made to address these problems in the related art. Specifically, object of the present invention is providing a substrate for a flexible electronic device which includes a polyimide layer having both a low ultraviolet light transmittance and a high visible light transmittance and capable of suppressing deterioration due to the ultraviolet light exposure without deteriorating performance of the electronic device. Another object of the present invention is to provide an organic thin film solar cell including the substrate for the flexible electronic device. Further, object of the present invention is to provide a laminated structure comprising a polyimide substrate and a peeling substrate, and in which the peeling substrate can be easily peeled off after the forming of an electronic element, and a method for manufacturing the same. Other object of the present invention is to provide a method for manufacturing the flexible electronic device using the same.

### Solution to Problem

The present invention provides the following substrate for a flexible electronic device.

[1] A substrate for a flexible electronic device comprising a polyimide layer, wherein the polyimide layer comprises following characteristics (1) to (3): (1) when the polyimide layer has a thickness of 5 μm, a maximum transmittance of light having a wavelength of 400±5 nm is 70% or more; (2) when the polyimide layer has a thickness of 5 μm, b* value of a L*a*b* colorimetric system is 5 or less; and (3) when the polyimide layer has a thickness of 5 μm, a transmittance of light having a wavelength of 350 nm is 10% or less.

[2] The substrate for a flexible electronic device according to [1], wherein the polyimide layer further comprises following characteristics (4) to (7): (4) when the polyimide layer has a thickness of 10 μm, a number of times of folding measured according to JIS P8115 in an MIT folding endurance test is 10,000 or more; (5) a glass transition temperature is 200° C. or higher; (6) a thickness is 10 μm or less; and (7) at least one surface has a surface roughness (Ra) of 5 nm or less.

[3] The substrate for a flexible electronic device according to [1] or [2], wherein the substrate further comprises a base material.

[4] The substrate for a flexible electronic device according to any one of [1] to [3], wherein the polyimide layer comprises a polyimide having a repeating structural unit represented by a following general formula (1) or a following general formula (2):

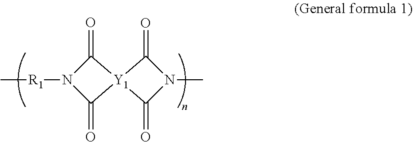

wherein in the general formula (1), R₁ is a divalent group having 4 to 15 carbon atoms including one or more alicyclic hydrocarbon structure(s) or a divalent linear aliphatic group having 5 to 12 carbon atoms, and Y₁ is a tetravalent group having 6 to 27 carbon atoms including aromatic ring or rings:

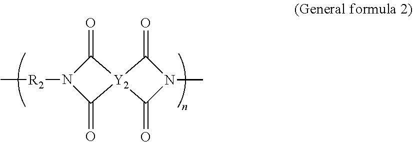

wherein in the general formula (2), R₂ is a divalent group having 6 to 27 carbon atoms including one or more aromatic ring(s), and Y₂ is a tetravalent group having 4 to 12 carbon atoms including one or more alicyclic hydrocarbon(s).

[5] The substrate for a flexible electronic device according to [4], wherein R₁ of the repeating structural unit represented by the general formula (1) is at least one divalent group selected from the group consisting of

—CH₂—CH₂—CH₂—CH₂—CH₂—,

—CH₂—CH₂—CH₂—CH₂—CH₂—CH₂—,

—CH₂—CH₂—CH₂—CH₂—CH₂—CH₂—CH₂—,

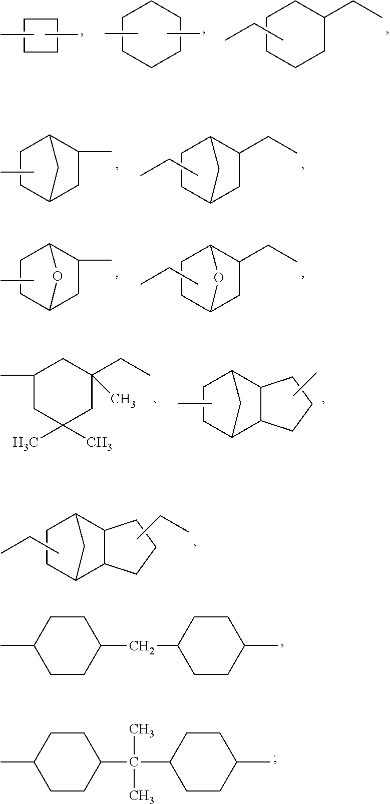

wherein Y₁ of the repeating structural unit represented by the general formula (1) is at least one tetravalent group selected from the group consisting of

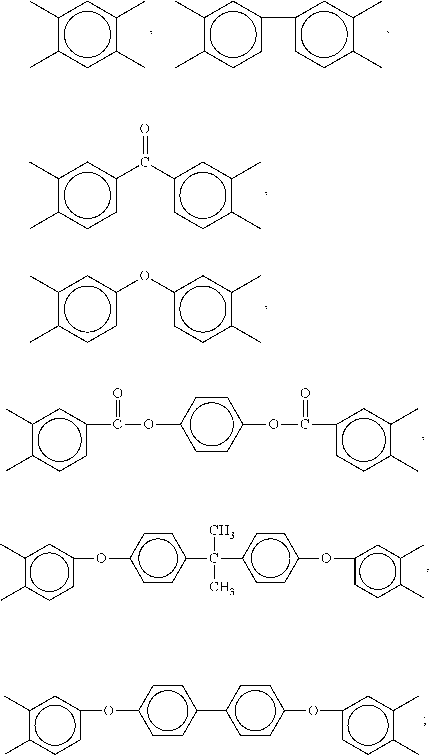

wherein R₂ of the repeating structural unit represented by the general formula (2) is at least one divalent group selected from the group consisting of

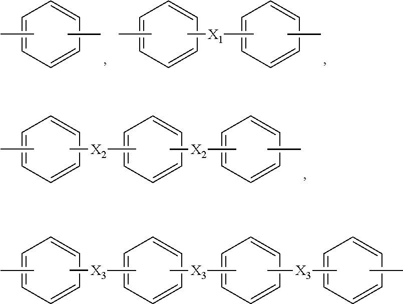

in the above formulae, X₁˜X₃ are each independently a single bond or a divalent group selected from the group consisting of

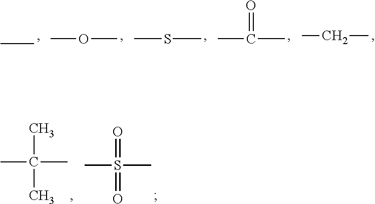

wherein Y₂ of the repeating structural unit represented by the general formula (2) is at least one tetravalent group selected from the group consisting of

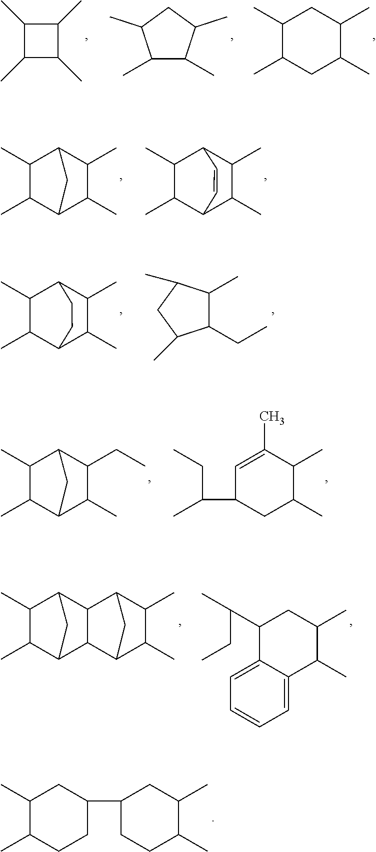

The present invention also provides the following organic thin film solar cells.

[6] An organic thin film solar cell, wherein the substrate for a flexible electronic element according to any one of [1] to [5], a first electrode, a photoelectric conversion layer, and a second electrode are stacked in this order.

The present invention also provides the following laminated structure.

[7] A laminated structure, comprising: a peeling substrate; a fluorine-based resin layer having a contact angle of 13° or more and 85° or less with water, the fluorine-based resin layer being disposed on the peeling substrate; and a polyimide substrate disposed adjacent to the fluorine-based resin layer, wherein, when the polyimide substrate has a thickness of 5 μm, a transmittance of light having a wavelength of 350 nm of the polyimide substrate is 10% or less.

[8] The laminated structure according to [7], wherein the polyimide substrate comprises a polyimide having a repeating structural unit represented by a following general formula (3) or a following general formula (4):

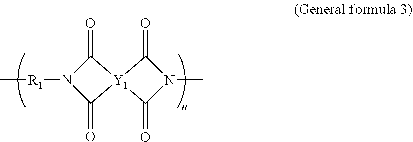

wherein, in the general formula (3), R₁ is a divalent group having 4 to 15 carbon atoms including one or more alicyclic hydrocarbon structure(s) or a divalent linear aliphatic group having 5 to 12 carbon atoms, and Y₁ is a tetravalent group having 6 to 27 carbon atoms including one or more aromatic ring(s):

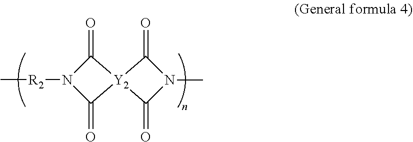

wherein in the general formula (4), R₂ is a divalent group having 6 to 27 carbon atoms including one or more aromatic ring(s), and Y₂ is a tetravalent group having 4 to 12 carbon atoms including alicyclic hydrocarbon structure or structures.

[9] The laminated structure according to [8], wherein R₁ of the repeating structural unit represented by the general formula (3) is at least one divalent group selected from the group consisting of

—CH₂—CH₂—CH₂—CH₂—CH₂—,

—CH₂—CH₂—CH₂—CH₂—CH₂—CH₂—,

—CH₂—CH₂—CH₂—CH₂—CH₂—CH₂—CH₂—,

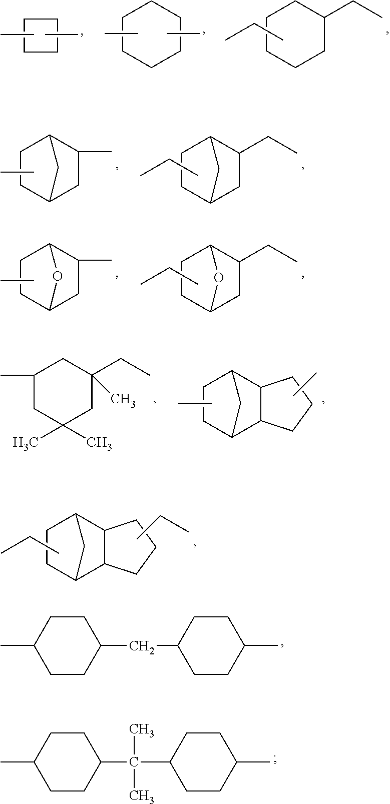

wherein Y₁ of the repeating structural unit represented by the general formula (3) is at least one tetravalent group selected from the group consisting of

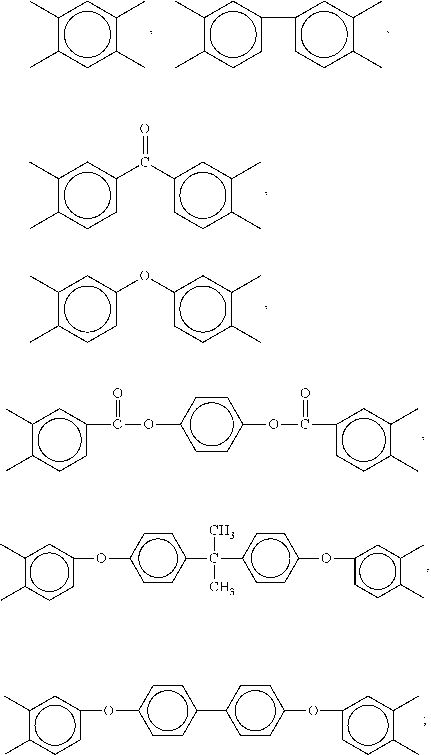

wherein R₂ of the repeating structural unit represented by the general formula (4) is at least one divalent group selected from the group consisting of

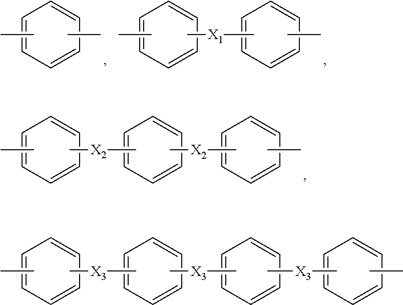

in the above formulae, X₁˜X₃ are each independently a single bond or a divalent group selected from the group consisting of

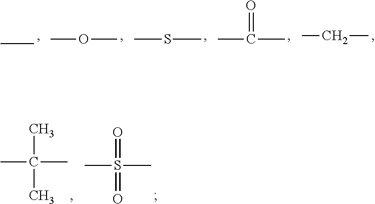

wherein Y₂ of the repeating structural unit represented by the general formula (4) is at least one tetravalent group selected from the group consisting of

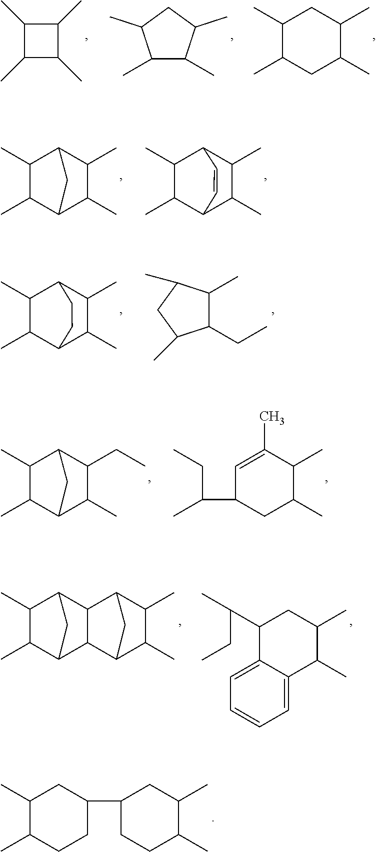

The present invention also provides the following method for manufacturing the laminated structure.

[10] A method for manufacturing a laminated structure described in [7] to [9], comprising: forming the fluorine-based resin layer on the peeling substrate; and forming the polyimide substrate on the fluorine-based resin layer; wherein the fluorine-based resin layer has a contact angle of 13° or more and 85° or less with water on a surface of the fluorine-based resin layer.

The present invention also provides the following method for manufacturing the flexible electronic device.

[11] A method for manufacturing a flexible electronic device, comprising: forming an electronic element on the polyimide substrate of the laminated structure according to any one of [7] to [9]; and peeling off the fluorine-based resin layer and the peeling substrate from the polyimide substrate after the forming of the electronic element.

### Advantageous Effects of Invention

Present invention provides a substrate for a flexible electronic device including a polyimide layer having both a low ultraviolet light transmittance and a high visible light transmittance and capable of suppressing deterioration due to the ultraviolet light exposure without deteriorating performance of the electronic device.

### DESCRIPTION OF EMBODIMENTS

In this specification, a numerical range represented by using “˜” means a range including a numerical value described before and after “˜” as a lower limit value and an upper limit value.

1. A Substrate for a Flexible Electronic Device

A substrate for a flexible electronic device (hereinafter also simply referred to as “device substrate”) of the present application is a substrate used for a flexible electronic device (hereinafter also simply referred to as an “electronic device”), and is a substrate for arranging various electronic elements on the substrate. Examples of electronic devices include solar cells such as organic thin film solar cells, LED devices, organic electroluminescent devices, transistors, and the like.

As described above, glass substrates have been mainly used as the substrate for the various electronic devices, such as the thin film solar cell. However, from the viewpoint of flexibility, the use of a resin substrate has been required. In addition, general electronic devices are susceptible to ultraviolet light. In Particular, thin film solar cells and the like used outdoors have a problem that their performance deteriorates when exposed to ultraviolet light for a long lime. Therefore, it has been examined to laminate such as UV cut filters on the device substrate. However, laminating a common UV cut filter make the device thicker and less flexible. In addition, in the thin film solar cell, there was also problem such as lowering of the photoelectric conversion efficiency.

On the other hand, the device substrate of the present application comprises a polyimide layer in which a transmittance of light having a wavelength of 350 nm is 10% or less, a maximum transmittance of light having a wavelength of 400±5 nm is 70% or more, and b* value of a L*a*b* colorimetric system is 5 or less. The device substrate including such the polyimide layer has very low transmittance of ultraviolet light having a wavelength of 350 nm or less. Further, such the device substrate has high transmittance of visible light and high transparency. Therefore, by replacing the conventional substrate, such as glass substrate or a resin substrate, with the device substrate of the present application, the electronic device can be driven for a long time with almost or no change in the appearance of the electronic device. In addition, since there is no need to laminate the UV cut filter on the electronic device, the electronic device can be made thinner, and a high degree of flexibility can be provided.

As described above, in the thin film solar cell, when ultraviolet light is shielded by the common UV cut filter, there is a problem that the photoelectric conversion efficiency is lowered. In contrast, in the thin film solar cell using the device substrate of the present application, the photoelectric conversion efficiency is hardly lowered.

Although the reason for this is not clear, it is considered that conventional UV cut filter may shield light in the wavelength range for photoelectric conversion, but such shielding is unlikely to occur in the device substrate (polyimide layer) of the present application. Further, another possible factor is that the device substrate (polyimide layer) has a coefficient of thermal expansion close to that of the photoelectric conversion layer of the thin film solar cell, which makes it difficult to deform during the fabrication of the thin film solar cell.

That is, according to the device substrate of the present application, it is possible to secure a thinness that enables flexibility, while suppressing deterioration of the device due to ultraviolet light exposure and ensuring sufficient photoelectric conversion efficiency. Further, by using the device substrate of the present application, it is possible to use a material which is susceptible to ultraviolet light as material of the device, which has the advantage of widening the choice of materials for device.

The device substrate of the present application may comprise only a polyimide layer. The device substrate of the present application may comprise the polyimide layer and a base material having transparency to visible light, flexibility, rigidity, and the like, which is laminated on the polyimide layer. When the polyimide layer and the base material are laminated, the polyimide layer functions as a layer to shield ultraviolet light. Note that the device substrate may optionally include one or more layers other than the polyimide layer and the base material. Hereinafter, the device substrate of the present invention will be described in detail.

1-1. Polyimide Layer

(Physical Properties)

The polyimide layer contained in the device substrate of the present application satisfies at least the following characteristics (1) to (3).

(1) when the polyimide layer has a thickness of 5 μm, a maximum transmittance of light having a wavelength of 400±5 nm is 70% or more.

(2) when the polyimide layer has a thickness of 5 μm, value of a L*a*b* colorimetric system is 5 or less.

(3) when the polyimide layer has a thickness of 5 μm, a transmittance of light having a wavelength of 350 nm is 10% or less.

When the polyimide layer has a thickness of 5 μm, (1) the maximum transmittance of light having a wavelength 400±5 nm of the polyimide layer is 70% or more, preferably 74% or more, more preferably 78% or more, further more preferably 80% or more, and particularly preferably 85% or more. When the maximum transmittance of light having the wavelength of 400±5 nm is within the above range, sufficient photoelectric conversion efficiency can be obtained by using the device substrate as a light receiving surface side substrate of the organic thin film solar cell. Further, when the device substrate is used as a light extraction side substrate of an organic EL device or the like, light can be sufficiently extracted from the device.

The maximum transmittance can be adjusted according to the type and structure of a polyimide constituting the polyimide layer. For example, by including an alicyclic group in a repeating structural unit of the polyimide, the maximum transmittance can be remarkably increased. The maximum transmittance can also be increased by adjusting the conditions at a time of polyimide production. Lowering the oxygen concentration in an inert atmosphere (e.g., under a nitrogen stream) during imidizing the polyamic acid can inhibit coloration due to oxidation and increase the maximum transmittance.

The light transmittance of the polyimide layer at the wavelength of 400±5 nm is measured by a spectrophotometer. In this specification, the maximum transmittance is defined as the maximum value of light transmittance measured within the wavelength range of 400±5 nm. Further, in this specification, the maximum transmittance is a value when the thickness of the polyimide layer is 5 μm. For example, the light transmittance of the polyimide layer can be measured with a polyimide layer having a thickness of 5 μm. On the other hand, the light transmittance may be measured with a polyimide layer having a different thickness and measured value may converted according to Lambert-Beer's law.

When the polyimide layer is laminated with the base material or the like, the light transmittance of the polyimide layer may be measured by peeling off the polyimide layer from the base material. On the other hand, the light transmittance of the polyimide layer may be specified by measuring the light transmittance of the entire device substrate and considering the light transmittance of the base material and the like from the measured value.

When the polyimide layer has a thickness of 5 μm, (2) the b* value of L*a*b* colorimetric system of the polyimide layer is 5 or less, preferably 4 or less, and more preferably 3 or less. Further, the b* value is preferably −1 or more. When the b* value is within the above range, the polyimide layer becomes colorless and visible light transmittance of the polyimide layer becomes excellent. That is, the sufficient photoelectric conversion efficiency can be obtained when the device substrate is used as the light receiving surface side substrate of the organic thin film solar cell. Further, when the device substrate is used as the light extraction side substrate of the organic EL device or the like, light can be sufficiently extracted from the device. The b* value can be adjusted by the structure of the polyimide, for example, by including a large number of alicyclic structures in the repeating structural unit of the polyimide, the b* value can be reduced. Further, the b* can be reduced by adjusting the conditions at the time of polyimide production. For example, lowering the oxygen concentration in an inert atmosphere (e.g., under a nitrogen stream) during imidizing the polyamic acid can inhibit coloration due to oxidation. Consequently, the b* value can be decreased.

The b* value of L*a*b* colorimetric system can be measured using the tester Color Cute i-type manufactured by Suga Test Instruments Co. Ltd. More specifically, after the tester is calibrated with a white reference plate, the b* value of the polyimide layer are measured in a transmission mode and a photometric method of 8° di. Note that, in this specification, the b* value is a value when the thickness of the polyimide layer is 5 μm, and the b* value may be measured for the polyimide layer having a thickness of 5 μm. On the other hand, the b* value of the polyimide layer may be specified by measuring the b* value of the polyimide layer having different thicknesses, and the measured value can be converted according to a conventional method.

Further, when the polyimide layer has a thickness of 5 μm, (3) the transmittance of light having a wavelength of 350 nm of polyimide layer is 10% or less, preferably 5% or less, more preferably 2% or less, and further more preferably 1% or less. On the other hand, a preferable lower limit value is 0%. When the transmittance of light having a wavelength of 350 nm of the polyimide layer is 10% or less, deterioration of various electronic devices by ultraviolet light exposure is sufficiently suppressed, and the various electronic devices can be used stably for a long time even in an environment exposed to ultraviolet light.

The light transmittance of the light having a wavelength of 350 nm of the polyimide layer can be measured by a spectrophotometer, and can be measured by the same method as the measurement method of the light transmittance at the wavelength of 400±5 nm described above. The light transmittance at the wavelength of 350 nm of the polyimide layer can be adjusted by the thickness of the polyimide layer and by an aromatic structure in the polyimide skeleton. By moderately extending the conjugated moiety in the polyimide skeleton, the transmittance of the light having a wavelength of 350 nm is likely to be lowered.

Further, when the polyimide layer has a thickness of 10 μm, (4) a number of times of folding measured according to JIS P8115 in an MIT folding endurance test is preferably 10,000 or more, more preferably 20,000 or more, further preferably 30,000 or more, particularly preferably 50,000 or more. When the number of times of folding measured in

MIT folding endurance test is 10,000 or more, the device substrate (polyimide layer) can be bent to be used for various electronic devices. Further, the number of times of folding measured in MIT folding endurance test is 10,000 or more, the device substrate has sufficient strength. In particular, when the number of times of folding measured in MIT folding endurance test is 30,000 or more, the device substrate is durable enough to be bent 30 times a day for three year. The number of times of folding can be adjusted, for example, by the structure of the polyimide. The number of times of folding can be increased by including a relatively flexible structure (e.g., a structure derived from an alicyclic diamine, a structure derived from an aliphatic diamine, or the like) in its repeating structural unit.

MIT folding endurance test can be performed by preparing the polyimide layer with a thickness of 10 μm, fixing one end of the test specimen with an MIT folding endurance tester (e.g., Type 307 manufactured by Yasuda Seiki Seisakusyo Ltd., etc.), grasping the other end of the test specimen and folding the test specimen repeatedly, and measuring the number of times of folding until the breakage.

In addition, the glass transition temperature of the polyimide layer is preferably 200° C. or more, more preferably 230° C. to 370° C., further more preferably 260° C. to 370° C., and particularly preferably 280° C. to 370° C. When the glass transition temperature of the polyimide layer is 200° C. or more, such as deformation is hardly generated in the device substrate (polyimide layer) when various electronic element is manufactured on the device substrate. Further, annealing treatment or other treatment may be performed at the time of manufacturing the organic thin film solar cell, and when the glass transition temperature of the polyimide layer is 200° C. or more, the device substrate can withstand such treatment. In particular, since the conductivity of transparent electrodes such as indium tin oxide (ITO) improves when the annealing temperature is raised, it is preferable that the glass transition temperature of the device substrate (polyimide layer) is high in such applications. The glass transition temperature of the polyimide layer can be adjusted by the equivalent of the imide group contained in the polyimide, the structure of the diamine component or the tetracarboxylic dianhydride component constituting the polyimide, and the like. The glass transition temperature is measured by a thermomechanical analyzer (TMA).

Further, (6) the thickness of the polyimide layer is preferably 10 μm or less. When the device substrate does not include the base material described later, that is, when the device substrate mainly comprises the polyimide layer, the thickness of the polyimide layer is preferably 0.5 μm to 5 μm, and more preferably 1 μm to 3 μm. When the thickness of the polyimide layer is 10 μm or less, the thickness of various devices using the device substrate can be reduced. Also when the thickness of the device substrate is 0.5 μm or more, the strength of the device can be sufficiently increased.

When the device substrate includes the base material described later, the thickness of the polyimide layer is preferably about several hundred nm to several tens of μm. When the thickness of the polyimide layer is several hundred nm or more, light having a wavelength of 350 nm or less can be sufficiently shielded by the polyimide layer, and such as the deterioration of the device can be suppressed. When the thickness of the polyimide layer is several tens of μm or less, it is possible to suppress the entire device substrate from becoming thick.

Further, (7) surface roughness (Ra) of at least one surface of the polyimide layer is preferably 5 nm or less, more preferably 2 nm or less, and further more preferably 1 nm or less. On the other hand, the lower limit value of the surface roughness is usually about 0.1 nm. When the surface roughness (Ra) of the polyimide layer is within the above range, problems such as short-circuiting hardly occur when the electronic element is formed on the polyimide layer. Only one side of the polyimide layer may have the surface roughness (Ra) in the above range, or both sides of the polyimide layer may have the surface roughness (Ra) in the above range. When the device substrate comprises the base material described later, the surface roughness (Ra) of the side on which the electronic element is formed (the surface opposite the base material) is preferably 5 nm or less.

The surface roughness of the polyimide layer can be adjusted by the method of forming the polyimide layer, for example, by forming a free surface by a applying method. Further, it is also possible to reduce the surface roughness by adjusting the temperature rise rate at the time of forming the polyimide layer (imidization), the viscosity and the concentration of the polyamic acid varnish, and the like. The surface roughness (Ra) can be measured by an atomic force microscope (AFM). It may be measured with a contact type surface roughness meter.

(Composition of the Polyimide Layer)

It is preferable that the polyimide layer contains polyimide having the repeating structural unit represented by the following general formula (1) and/or the repeating structural unit represented by the following general formula (2). The polyimide may comprise only one of the repeating structural units represented by the general formula (1) and general formula (2), or both. In addition, the polyimide may comprise a repeating structural unit other than the repeating structural unit represented by the general formula (1) and/or the repeating structural unit represented by the general formula (2). However, the total amount of the repeating structural unit represented by the general formula (1) and the repeating structural unit represented by the general formula (2) is preferably 50 mol % or more, more preferably 80 mol % or more, further more preferably 90 mol % or more, and particularly preferably 95 mol % or more, based on the total amount of the repeating structural units comprised in the polyimide. When the total amount of these is 50 mol % or more, a polyimide layer tends to have the above-mentioned physical properties, and physical properties of the polyimide layer tend to be uniform in the entire layer.

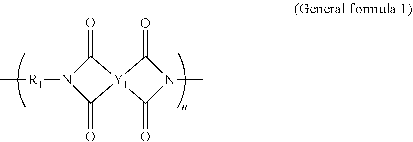

In the above general formula (1), R₁ is a divalent group having 4 to 15 carbon atoms including one or more alicyclic hydrocarbon structure(s), or a divalent linear aliphatic group having 5 to 12 carbon atoms. Specific examples of R₁ include following divalent groups:

—CH₂—CH₂—CH₂—CH₂—CH₂—,

—CH₂—CH₂—CH₂—CH₂—CH₂—CH₂—,

—CH₂—CH₂—CH₂—CH₂—CH₂—CH₂—CH₂—,

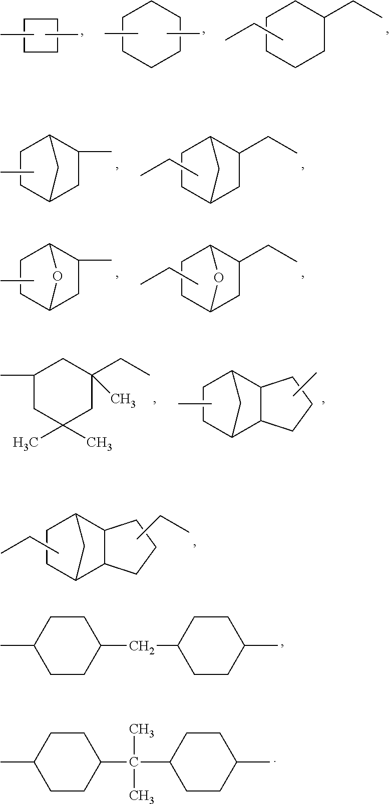

Of these,

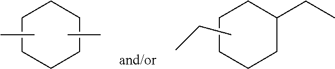

are preferable as R₁.

On the other hand, in the above general formula (1), Y₁ is a tetravalent group having 6 to 27 carbon atoms including one or more aromatic ring(s). Specific examples of Y₁ include following tetravalent groups:

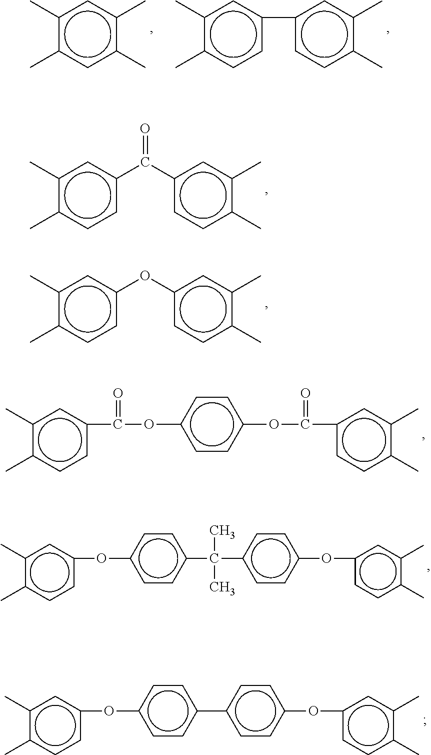

Of these,

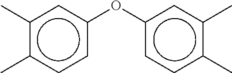

is preferable as Y₁.

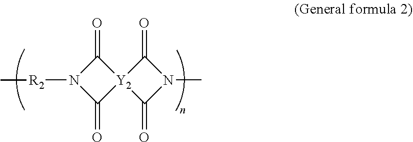

In the above general formula (2), R₂ is a divalent group having 6 to 27 carbon atoms including one or more aromatic ring(s). Specific examples of R₂ include following divalent groups:

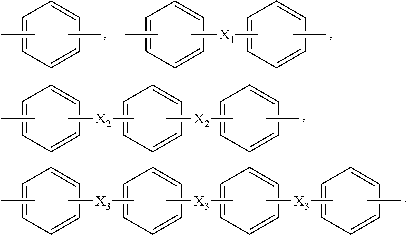

In the above formulae, each X₁˜X₃ is a single bond or the following divalent group independently. When one repeating structural unit contains more than one X₂ or X₃, they may be identical or different from each other.

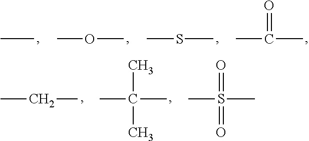

On the other hand, Y₂ in the above general formula (2) represents a tetravalent group having 4 to 12 carbon atoms including one or more alicyclic hydrocarbon structure(s). Specific examples of Y₂ include the following tetravalent groups:

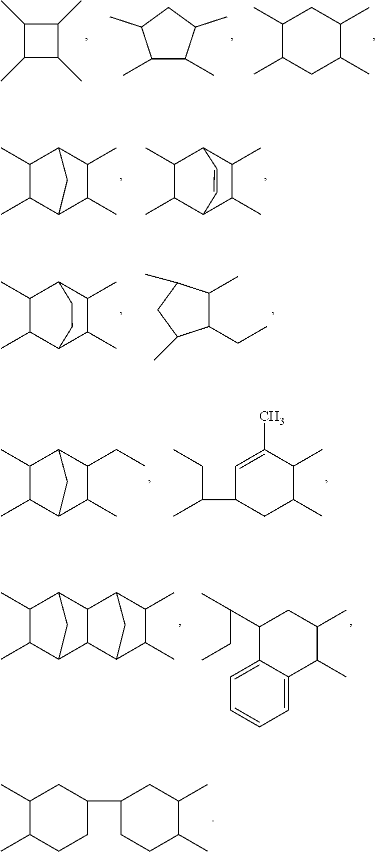

1-2. Base Material and Other Layers

In the device substrate of the present application may comprise a base material or other layers to the extent that it does not impair the purpose and effect of the present invention.

The base material comprised in the device substrate preferably has the same or greater flexibility (MIT folding endurance) and visible light transmittance (maximum transmittance at a wavelength of 400±5 nm) than the above described polyimide layer. Further, the b* of L*a*b* colorimetric system is preferably 5 or less. Examples of the base material include such as a resin film applicable to a substrate of a conventional organic thin film solar cell. Examples thereof include polyester films, such as polyethylene terephthalate (PET) film or polyethylene naphthalate (PEN) film, a parylene film, a polyamide film, and the like.

The device substrate may optionally include other layers, examples of such layers include a gas barrier layer, a surface hard coat layer, and the like.

Note that the thickness of the base material and other layers is preferably sufficiently thin, and is preferably 10 μm or less together with the polyimide layer.

1-3. Method for Manufacturing Device Substrate

The method for manufacturing the above described device substrate is not particularly limited as long as it can be formed so as to include the above described polyimide layer, and is appropriately selected according to the configuration of the device substrate.

For example, when the device substrate is composed only of a polyimide layer, a polyamic acid varnish is prepared by polymerizing a diamine having a specific structure and a tetracarboxylic dianhydride having a specific structure in a solvent. Then, the polyamic acid varnish is applied on a support. Thereafter, the polyamic acid is imidized (imide ring-closing) on the support and the support is peeled off from the polyimide layer (the device substrate). However, when the polyamic acid varnish is directly applied on the support and the polyamic acid is imidized on the support, it may be difficult to peel off the support from the device substrate (polyimide layer). Therefore, it is preferable to manufacture such the device substrate by a method described later in “laminated structure”. Note that diamines, tetracarboxylic dianhydrides, solvents, various manufacturing conditions, and the like for producing a polyimide layer will be described in detail in the column of “laminated structure”

On the other hand, when the device substrate includes the polyimide layer and the base material, the above-mentioned polyamic acid varnish is applied on the base material so as to be a desired thickness and imidized, whereby the device substrate can be obtained.

2. Organic Thin Film Solar Cell

The device substrate described above can be used as a substrate of an organic thin-film solar cell. As described above, the device substrate of the present application has low transmittance of light having a wavelength of 350 nm or less and high transmittance of light having a wavelength of 400 nm or more. In view of this, particularly by applying it to an organic thin film solar cell having a maximum absorption wavelength in a region exceeding a wavelength of 350 nm, the effect can be sufficiently exhibited.

The organic thin film solar cell of the present application may have a configuration in which the device substrate, a first electrode, a photoelectric conversion layer, and a second electrode are stacked in this order. For example, the organic thin film solar cell may have a configuration in which the device substrate (light receiving surface side substrate)/the first electrode/an electron transport layer/a photoelectric conversion layer/a hole transport layer/the second electrode/back side substrate are stacked in this order. However, the configuration of the organic thin film solar cell is not limited to above configuration.

The light receiving surface side substrate is the above described device substrate. The device substrate has both low ultraviolet light transmittance and high visible light transmittance. Therefore, by using the device substrate as the light receiving surface side substrate of the organic thin-film solar cell, destruction of the photoelectric conversion layer can be suppressed without lowering the photoelectric conversion efficiency.

The first electrode may be a negative electrode. Since the first electrode is located on the light receiving surface side of the organic thin film solar cell, it is preferable that the first electrode is a layer containing a transparent conductive metal compound such as silver (silver nanowires, silver mesh, or the like), indium tin oxide (ITO), aluminum zinc oxide (AZO), indium zinc oxide (IZO), or a layer containing a two dimensional material such as graphene.

Further, the electron transport layer is disposed between the first electrode and the photoelectric conversion layer, and is a layer to facilitate the transfer of electrons from the photoelectric conversion layer to the first electrode. Incidentally, the electron transport layer may be responsible for making it difficult for holes to move from the photoelectric conversion layer to the first electrode. The electron transport layer may be formed of a material having a high electron mobility, and may be a layer containing a known organic semiconductor molecule or an inorganic compound such as ZnO.

The photoelectric conversion layer can be a layer in which a known p-type organic semiconductor having an electron donating property and a known n-type organic semiconductor having an electron accepting property and forming a bulk heterojunction are mixed at a nano level. The example of p-type organic semiconductor is a polymer compound described in Japanese Patent Application Laid-Open No. 2016-17117. On the other hand, the n-type organic semiconductor includes carbon materials such as fullerene, fullerene derivatives, carbon nanotubes, and carbon nanotubes having chemical modifications; and metal complexes having ligand such as fused ring aromatic compounds, 5 to 7-membered heterocyclic compounds, polyarylene compounds, fluorene compounds, cyclopentadiene compounds, silyl compounds, and nitrogen-containing heterocyclic compounds. It is also effective to use a perovskite type compound for the photoelectric conversion layer, depending the purpose. Further, a light emitting device can be formed by using a current or electroluminescent material in the photoelectric conversion layer, depending on the purpose.

Further, the hole transport layer is disposed between the second electrode and the photoelectric conversion layer, and is a layer to facilitate the transfer of holes from the photoelectric conversion layer to the second electrode. Incidentally, the hole transport layer may be responsible for making it difficult for electrons to move from the photoelectric conversion layer to the first electrode. The hole transporting layer may comprises a known conductive polymer, an inorganic compound such as MoO₃, WO₃, an organic semiconductor molecule, or the like.

Further, the second electrode may be an anode. The material of the second electrode may be any material as long as it has conductivity. For example, a layer containing a metal such as Au, Pt, Ag, Cu, Al, Mg, Li, or K, a carbon electrode, or the like can be used as the second electrode.

The backside substrate is not particularly limited, and the same substrate as that used in a known organic thin film solar cell can be used. Incidentally, the device substrate described above may be used as the back side substrate.

The method for manufacturing the organic thin film solar cell is not particularly limited, but it is preferable to sequentially laminate each layer on the device substrate (the light receiving surface side substrate). At this time, as described below in the “method for manufacturing a flexible electronic device using a laminated structure”, it is preferable to fix the device substrate (polyimide substrate) on the peeling substrate, stack the layers, and peel off the peeling substrate from the device substrate (polyimide substrate).

3. Laminated Structure

The laminated structure of the present application has a structure in which a peeling substrate, a fluorine-based resin layer, and a polyimide substrate are laminated.

In general, when an electronic element is formed on a flexible substrate, the flexible substrate tends to be bent or distorted, which may cause the position of the electronic element to shift or the resulting electronic device to be distorted. Therefore, the electronic element may be formed with the substrate fixed to the peeling substrate or the like. However, in this method, after the forming of the electronic element, it is difficult to peel off the peeling substrate from the substrate. Additionally, the resulting electronic device are susceptible to damage.

In contrast, in the laminated structure of the present application, the polyimide substrate for forming the element and the peeling substrate are laminated via a fluorine-based resin layer. Therefore, after the forming of the electronic element on the polyimide substrate of the laminated structure, it is possible to easily peel off at the interface between the polyimide substrate and the fluorine-based resin layer. Hereinafter, each structure of the laminated structure of the present invention will be described.

3-1. Peeling Substrate

The peeling substrate is not particularly limited as long as it has rigidity capable of sufficiently supporting the polyimide substrate and is a substrate capable of uniformly forming the fluorine-based resin layer to be described later on its surface. The shape of the peeling substrate is appropriately selected in accordance with the shape of the electronic element to be formed, and may be, for example, a flat substrate, a substrate having a bent structure, or the like.

The material of the peeling substrate is not particularly limited, and may be an alkali glass substrate that contains an alkali metal oxide (Na₂O, K₂O) or a non-alkali glass substrate. A Si wafer, a polymer film having high rigidity, or the like may be used as a peeling substrate.

Further, the thickness of the peeling substrate is preferably 50 to 3000 μm, more preferably 100 to 1000 μm, and further more preferably 100 to 700 μm. When the thickness of the peeling substrate is in the range, the handling property when forming the electronic element on the laminated structure is improved. Further, the strength of the laminated structure is likely to increase. Incidentally, the strength of the inorganic glass substrate having a thickness of 100 μm or less may be slightly low. When such the inorganic glass substrate is used as the peeling substrate, the inorganic glass substrate is preferably treated with a hardening resin to fill in the cracks on the surface, which makes the inorganic glass substrate less likely to crack.

The surface roughness (Ra) of the surface of the peeling substrate on which the polyimide substrate is stacked is preferably sufficiently small, preferably 10 nm or less, and more preferably 5 nm or less. Surface roughness (Ra) can be measured by atomic force microscopy (AFM). The surface roughness (Ra) can also be measured by a contact type surface roughness meter. When the surface roughness (Ra) becomes large, the peeling substrate tends to be cracked, or the peeling substrate tends to be difficult to peel off from the polyimide substrate. Further, when forming the electronic element on the polyimide substrate, backscatter may increase due to the presence of the such peeling substrate.

3-2. Fluorine-Based Resin Layer

The fluorine-based resin layer is a layer formed between the peeling substrate and the polyimide substrate, and is a layer containing a resin comprising fluorine in the molecular structure. The water contact angle of the surface of the fluorine-based resin layer is 13° or more and 85° or less, and the water contact angle is preferably 23° or more and 80° or less, and more preferably 23° or more and 70° or less. As described later, the polyimide substrate is usually formed by applying a varnish or the like containing a polyamic acid on the fluorine-based resin layer.

At this time, if the water contact angle of the surface of the fluorine-based resin layer is too high, the varnish is repelled, and the polyimide substrate cannot be uniformly formed. On the other hand, when the water contact angle of the surface of the fluorine-based resin layer is 85° or less, the polyimide substrate can be uniformly formed without unevenness. On the other hand, if the water contact angle of the surface of the fluorine-based resin layer is too low, peeling at the interface between the polyimide substrate and the fluorine-based resin layer becomes difficult when the peeling substrate and the fluorine-based resin layer are peeled off from the polyimide substrate after forming of the electronic element. However, when the contact angle of the surface of the fluorine-based resin layer with water is set to 13° or more, excellent peelability can be obtained. The water contact angle of the surface of the fluorine-based resin layer can be adjusted by the type of the fluorine-based resin layer, the surface treatment of the fluorine-based resin layer, and the like.

The water contact angle of the surface of the fluorine-based resin layer is a water contact angle when the fluorine-based resin layer is exposed, and can be measured, for example, by peeling off the polyimide substrate from the laminated structure. Further, the water contact angle of the surface of the fluorine-based resin layer can be measured by a droplet method.

The fluorine-based resin layer can be formed, for example, by applying a known fluorine-based resin (e.g., hydrofluoroether) to the peeling substrate and drying it. Examples of commercially available products of the fluorine-based resin include Novec 2702, 1700, 1720, 7000, 7100, 7200, 7300, 71IPE (all manufactured by 3M Co., Ltd.); Teflon (registered trademark) AF1600, AF2400 (all manufactured by Du Pont Mitsui Fluorochemicals Co., Ltd.), and the like. These may be used alone or as a mixture of two or more thereof.

Further, the fluorine-based resin layer may be subjected to an oxygen plasma treatment, after forming of the layer containing the fluorine-based resin. By the oxygen plasma treatment, the water contact angle of the fluorine-based resin layer can be adjusted to a desired range.

The thickness of the fluorine-based resin layer is preferably 0.01 to 10 μm, more preferably 0.1 to 3 μm. When the thickness of the fluorine-based resin layer is 0.01 μm or more, peelability from the polyimide substrate tends to be sufficiently increased.

3-3. Polyimide Substrate

The polyimide substrate is a substrate for forming the flexible electronic device. In the polyimide substrate, when the thickness is 5 μm, the transmittance of light having wavelength of 350 nm is 10% or less. The polyimide substrate preferably has the same physical properties as the polyimide layer of the device substrate described above.

3-4. Method for Manufacturing Laminated Structure

The laminated structure described above can be manufactured by forming the fluorine-based resin layer on the peeling substrate and forming the polyimide substrate on the fluorine-based resin layer.

(Forming Fluorine-Based Resin Layer)

First, the aforementioned peeling substrate is prepared, and a composition for forming the fluorine-based resin layer is applied on the peeling substrate. The composition for forming the fluorine-based resin layer may be a composition containing the aforementioned fluorine-based resin or a precursor thereof and a solvent.

The applying method of the composition for forming the fluorine-based resin layer is not particularly limited, and can be, for example, spin coating method, bar coating method, dip coating method, slit coating method, spray coating method, gravure coating method, dye coating method, or the like.

After applying the composition for forming the fluorine-based resin layer, the solvent in the composition is removed and dried. The drying method is appropriately selected depending on the component contained in the composition. For example, it may be heat-drying or drying at room temperature.

Further, after drying of the composition for forming the fluorine-based resin layer, the surface of the layer may treated with an oxygen plasma, if necessary. The treatment condition of the oxygen plasma is appropriately selected so that the water contact angle of the surface of the fluorine-based resin layer becomes 13° or more and 85° or less.

(Forming Polyimide Substrate)

Subsequently, the polyimide substrate is formed on the fluorine-based resin layer described above. A diamine having a specific structure and a tetracarboxylic dianhydride having a specific structure are subjected to a polymerization reaction in a solvent to obtain a polyamic acid varnish. Then, the polyamic acid varnish is applied on the fluorine-based resin layer, and then the polyamic acid is imidized (imide ring-closing). Thus, the laminated structure in which the peeling substrate, the fluorine-based resin layer, and the polyimide substrate are laminated is obtained. The details will be described below.

(Preparation of Polyamic Acid Varnish)

First, a diamine having a specific structure and a tetracarboxylic dianhydride having a specific structure are subjected to a polymerization reaction in a solvent to obtain a polyamic acid varnish.

The diamine and the tetracarboxylic dianhydride are appropriately selected according to the structure of the polyimide to be prepared. For example, in preparing the device substrate containing polyimide having repeating structural unit represented by the above general formula (1), the polyamic acid is prepared by reacting diamine including alicyclic hydrocarbon structure(s) or linear aliphatic diamine(s) with tetracarboxylic dianhydride including aromatic ring(s). Each of the diamine and the tetracarboxylic dianhydride may be used alone, and two or more of them may be used in combination.

Examples of diamines including alicyclic hydrocarbon structure(s) include cyclobutanediamine, cyclohexanediamine, bis (aminomethyl) cyclohexane, diaminobicycloheptane, diaminomethyl bicycloheptane (including norbornanediamines such as norbornanediamine), diaminooxybicycloheptane, diaminomethyloxy bicycloheptane (including oxanorbornanediamine), isophoronediamine, diaminotricyclodecane, diaminomethyl tricyclodecane, bis(aminocyclohexyl)methane, bis(aminocyclohexyl) isopropylidene, and the like.

Examples of linear aliphatic diamines include 1,5-diaminopentane, 1,6-diaminohexane, 1,7-diaminoheptane, 1,8-diaminooctane, 1,9-diaminononane, 1,10-diaminodecane, 1,11-diaminoundecane, 1,12-diaminododecane, and the like.

In addition, examples of tetracarboxylic dianhydrides including aromatic ring(s) include pyromellitic dianhydride, 3,3′,4,4′-biphenyltetracarboxylic dianhydride, 2,3,3′,4′-biphenyltetracarboxylic dianhydride, 3,3′,4,4′-benzophenone tetracarboxylic dianhydride, bis(3,4-dicarboxyphenyl)ether dianhydride, 1,4-bis(3,4-dicarboxyphenoxy)benzene dianhydride, 2,2-bis[(3,4-dicarboxyphenoxy)phenyl]propane dianhydride, 4,4′-bis(3,4-dicarboxyphenoxy)biphenyl dianhydride, naphthalene 2,3,6,7-tetracarboxylic dianhydride, naphthalene 1,2,5,6-tetracarboxylic dianhydride, 4,4′-(9-fluorenylidene)bisphthalic anhydride, and the like.

On the other hand, in preparing the device substrate containing polyimide having repeating structure unit represented by the above general formula (2), the polyamic acid is prepared by reacting diamine including aromatic ring(s) with tetracarboxylic dianhydride including alicyclic hydrocarbon structure(s). Each of the diamine and the tetracarboxylic dianhydride may be used alone, and two or more of them may be used in combination.

Examples of diamines including aromatic ring(s) are diamines including one benzene ring such as p-phenylenediamine, m-phenylenediamine, p-xylylenediamine, m-xylylenediamine; diamines including two benzene rings such as 3,4′-diaminodiphenyl ether, 4,4′-diaminodiphenyl ether, 3,3′-diaminodiphenyl sulfide, 4,4′-diaminodiphenyl sulfide, 3,3′-diaminodiphenyl sulfone, 4,4′-diaminodiphenyl sulfone, 3,3′-diaminobenzophenone, 4,4′-diaminobenzophenone, 3,3′-diaminodiphenylmethane, 4,4′-diaminodiphenylmethane, 2,2-di(4-aminophenyl)propane, 1,5-diaminonaphthalene; diamines including three benzene rings such as 1,3-bis(3-aminophenoxy)benzene, 1,3-bis(4-aminophenoxy)benzene, 1,4-bis(3-aminophenoxy)benzene, 1,4-bis(4-aminophenoxy)benzene, 1,3-bis(3-aminobenzoyl)benzene, 1,3-bis(4-aminobenzoyl)benzene, 1,4-bis(3-aminobenzoyl)benzene, 1,4-bis(4-aminobenzoyl)benzene, 2,6-bis(3-aminophenoxy)pyridine; diamines including four benzene rings such as 4,4′-bis(3-aminophenoxy)biphenyl, 4,4′-bis(4-aminophenoxy)biphenyl, bis[4-(3-aminophenoxy)phenyl]ketone, bis[4-(4-aminophenoxy)phenyl]ketone, bis[4-(3-aminophenoxy)phenyl]sulfide, bis[4-(4-aminophenoxy)phenyl]sulfide, bis[4-(3-aminophenoxy)phenyl]sulfone, bis[4-(4-aminophenoxy)phenyl]sulfone, bis[4-(3-aminophenoxy)phenyl]ether, bis[4-(4-aminophenoxy)phenyl]ether, 2,2-bis[4-(4-aminophenoxy)phenyl]propane; and the like.

On the other hand, examples of tetracarboxylic dianhydrides including alicyclobutane hydrocarbon structure(s) include cyclobutane tetracarboxylic dianhydride, 1,2,3,4-cyclopentanetetracarboxylic dianhydride, 1,2,4,5-cyclohexanetetracarboxylic dianhydride, bicyclo[2.2.1]heptane-2,3,5,6-tetracarboxylic anhydride, bicyclo[2.2.2]oct-7-ene-2,3,5,6-tetracarboxylic anhydride, bicyclo[2.2.2]octane-2,3,5,6-tetracarboxylic dianhydride, 2,3,5-tricarboxylic dianhydride, bicyclo[2.2.1]heptane-2,3,5-tricarboxylic-6-acetic dianhydride, 1-methyl-3-ethylcyclohexa-1-ene-3-(1,2), 5,6-tetracarboxylic dianhydride, decahydro-1,4,5,8-dimethanonaphthalene-2,3,6,7-tetracarboxylic dianhydride, 4-(2,5-dioxotetrahydrofuran-3-yl)-tetralin-1,2-dicarboxylic dianhydride, 3,3′,4,4′-dicyclohexyltetracarboxylic dianhydride, and the like.

The polyamic acid varnish is obtained by polymerizing the above diamine and the tetracarboxylic dianhydride in an aprotic polar solvent or a water-soluble alcohol-based solvent. Examples of aprotic polar solvents include N-methylpyrrolidone, N,N-dimethylformamide, N,N-dimethyl acetamide, dimethyl sulfoxide, hexamethylphosphoramide, and the like; and ether compounds such as 2-methoxyethanol, 2-ethoxyethanol, 2-(methoymethoxy)ethoxyethanol, 2-isopropoxyethanol, 2-butoxyethanol, tetrahydrofurfuryl alcohol, diethylene glycol, diethylene glycol monomethyl ether, diethylene glycol monoethyl ether, diethylene glycol monobutyl ether, triethylene glycol, triethylene glycol monoethyl ether, tetraethylene glycol, 1-methoxy-2-propanol, 1-ethoxy-2-propanol, dipropylene glycol, dipropylene glycol monomethyl ether, dipropylene glycol monoethyl ether, tripropylene glycol monomethyl ether, polyethylene glycol, polypropylene glycol, tetrahydrofuran, dioxane, 1,2-dimethoxyethane, diethylene glycol dimethyl ether, diethylene glycol diethyl ether, and the like. Examples of water-soluble alcohol-based solvents include methanol, ethanol, 1-propanol, 2-propanol, tert-butyl alcohol, ethylene glycol, 1,2-propanediol, 1,3-propanediol, 1,3-butanediol, 1,4-butanediol, 2,3-butanediol, 1,5-pentanediol, 2-buten-1,4-diol, 2-methyl-2,4-pentanediol, 1,2,6-hexanetriol, diacetone alcohol, and the like.

These solvents may be used alone or as a mixture of two or more thereof. Of these, N,N-dimethylacetamide, N-methylpyrrolidone or a combination thereof are preferred.

There is no particular limitation on the preparation procedure of the polyamic acid varnish. For example, a container equipped with an agitator and a nitrogen introduction pipe is prepared. The aforementioned solvent is charged into the container in which nitrogen is replaced, and the diamine is added so that the solid concentration is about 30% by mass, and the mixture is stirred and dissolved. To this solution, the tetracarboxylic dianhydride is added so that the molar ratio of the tetracarboxylic dianhydride to the diamine is about 1, and the temperature is adjusted and stirred for about 1 to 50 hours. Thus, the polyamic acid varnish in which the polyamic acid is dispersed in a solvent can be obtained.

(Application of Polyamic Acid Varnish and Imidization)

The polyamic acid varnish described above is applied on the aforementioned fluorine-based resin layer, heated, and the polyamic acid is imidized. The application method of polyamic acid varnish is not particularly limited, such as spin coating method, bar coating method, dip coating method, slit coating method, spray coating method, gravure coating method, dye coating method, and so on.

The imidization of the polyamic acid can be carried out in a normal heating and drying furnace. As an atmosphere of the drying furnace, air, inert gas (nitrogen, argon), or the like can be used. Especially, an inert gas atmosphere having an oxygen concentration of 5% or less is preferably used. By lowering the oxygen concentration in the environmental atmosphere, the transparency of the obtained device substrate (polyimide substrate) can be increased. Further, folding endurance and tensile strength of the resulting device substrate (polyimide substrate) is also likely to increase. The oxygen concentration in the environmental atmosphere of the inert gas is more preferably 0.1% or less.

On the other hand, the average temperature rise rate at the time of imidization can be, for example, 0.25 to 50° C. per minute in the range of 50 to 300° C., preferably 1 to 10° C. per minute, more preferably 2 to 5° C. per minute. The average temperature rise rate may be constant or may be changed in two or more stages. When the average temperature rise rate is changed in two or more stages, it is preferable to set each average temperature rise rate to 0.25 to 50° C. per minute. As a result, the obtained polyimide substrate has high transparency, high tensile strength and folding endurance. Further, although the temperature rise may be continuous or stepwise (sequential), it is preferable to make it continuous from the viewpoint of suppressing the appearance defect of the obtained polyimide substrate and suppressing the whitening accompanying the imidization. Note that the coating film does not necessarily need to be heated to 300° C. When the end temperature is less than 300° C., it is preferable to set the average temperature rise rate from 150° C. to the end temperature in the range of 0.25° C. to 50° C. per minute.

The end temperature (maximum attainable temperature) is usually preferred to be set at a relative high temperature. Specifically, it is preferable to set the end temperature to be at least 10° C. higher than the glass transition temperature Tg of the polyimide. By setting the end temperature (maximum attainable temperature) to the above temperature, it is easy to remove the remaining solvent contained in the coating film. In addition, folding endurance of the obtained polyimide substrate becomes high. The end temperature (maximum attainable temperature) is preferably 200 to 300° C., more preferably 250 to 290° C., and further more preferably 270 to 290° C. After the temperature is raised to the end temperature, it is preferably maintained at the temperature for about 1 second to 10 hours.

4. Method for Manufacturing Flexible Electronic Devices Using Laminated Structures

In the case of manufacturing a flexible electronic devices using the above described laminated structure, the electronic element is formed on the polyimide substrate of the laminated structure, and then the peeling substrate and the fluorine-based resin layer are removed from the polyimide substrate.

According to the method of the present application, the electronic element can be formed while supported by the rigid peeling substrate. Therefore, when the electronic element is formed, the polyimide substrate does not bend, and the electronic element can be formed at a desired position with high accuracy.

On the other hand, after forming the electronic element, it is possible to easily peel off the peeling substrate and the fluorine-based resin layer from the polyimide substrate. Therefore, it is possible to peel off the peeling substrate without damaging the electronic element, and it is easy to obtain flexible electronic devices.

### EXAMPLES

In the following, the invention will be explained with reference to examples. The examples are not to be construed as limiting the scope of the invention.

1. Manufacturing of Laminated Structures

### Example 1

(Forming Fluorine-Based Resin Layer)

200 μl of fluorine-based resin layer composition obtained by mixing a fluorine-based coating agent 1 (manufactured by 3M Co., Ltd., NOVEC 270) and a fluorine-based coating agent 2 (manufactured by 3M Co., Ltd., NOVEC200) at a mass ratio of 1:1 was dropped onto a peeling substrate made of an inorganic glass plate (alkali glass, 0.7 mm thickness), and spin-coated. The spin coating conditions were 1000 rpm for 60 seconds. Thereafter, the laminate was left at room temperature for 3 minutes to form a fluorine-based resin layer having a thickness of 100 nm on the inorganic glass plate. The surface of the obtained fluorine-based resin layer was subjected to an oxygen plasma treatment. The plasma treatment was carried out for 30 seconds at an oxygen-gas flow rate of 5 sccm and a power of 50 W using PC300 manufactured by SAMCO Co. Ltd.

(Forming Polyimide Substrate (Device Substrate))

5.71 g (0.05 mol) of 1,4-diaminocyclohexane (CHDA), 7.11 g (0.05 mol) of 1,4-bis (aminomethyl) cyclohexane (14BAC), and 229.7 g of N,N-dimethylacetamide (DMAc) was added to a 300 mL 5 necked separable flask equipped with a thermometer, an agitator, a nitrogen introduction tube, and a dropping funnel, and stirred.

30.9 g (0.1 mol) of bis(3,4-dicarboxyphenyl)ether dianhydride (ODPA) was added to the flask, and the reaction vessel was bathed in an oil bath held at 120° C. for 5 minutes. Its rapid re-dissolution was observed. After removing the oil bath, the mixture was stirred at room temperature for another 18 hours to obtain polyamic acid varnish containing polyamic acid. The polyamic acid varnish was dropped onto the above-mentioned fluorine-based resin layer at a rate of 200 μl per cm² and spin-coated on the fluorine-based resin layer. The spin coating conditions were 5,000 rpm for 60 seconds. Thereafter, the laminate was heated to 270° C. at the temperature rise rate of 2° C. per minute in an inert oven, and fired at 270° C. for 2 hours. As a result, the polyimide substrate (the device substrate) having a thickness of 1 μm was formed on the inorganic glass plate.

<Evaluation>

On the polyimide substrate (the substrate for the flexible electronic device), the following evaluation was carried out. Note that the separately prepared inorganic glass plate (alkali glass, 0.7 mm thickness) and the parylene film were set as Comparative Example 1-1 and Comparative Example 1-2, respectively, and the same evaluation was carried out on these.

a. Transmittance of Light Having a Wavelength of 350 nm and Measurement of Maximum Transmittance of Light Having a Wavelength of 400 nm±5 nm for the Polyimide Substrate with Thickness of 5 μm

Polyimide substrate with thickness of 5 μm were prepared using the above polyamic acid varnish. In the forming of the polyimide substrate, only the spin coating conditions was changed from the forming of the polyimide substrate described above. The transmittance of light having a wavelength of 350 nm and the maximum transmittance of light having a wavelength of 400 nm±5 nm of the polyimide substrate were measured by a spectrophotometer (Multi Spec-1500) manufactured by Shimadzu Corporation. Similarly, the transmittance of light having a wavelength of 350 nm and the maximum transmittance of light having a wavelength of 400 nm±5 nm of the inorganic glass plate (Comparative Example 1-1) and the parylene film having a thickness of 5 μm (Comparative Example 1-2) were measured.

b. b* Value in L*a*b* Colorimetric System for the Polyimide Substrate with Thickness of 5 μm

Polyimide substrate with thickness of 5 μm were prepared using the above polyamic acid varnish. In the forming of the polyimide substrate, only the spin coating conditions was changed from the forming of the polyimide substrate described above. The b* value in L*a*b* colorimetric system of the polyimide substrate were measured by Suga Test Instrument Co., Ltd. in a transmission mode and a photometric method of 8° di after calibrating with a white standard plate. Similarly, the b* values of the inorganic glass plate (Comparative Example 1-1) and the parylene film (Comparative Example 1-2) having a thickness of 5 μm were also measured. For the inorganic glass plate, the measured b* value was converted into b* value for inorganic glass plate with thickness of 5 μm.

c. MIT Folding Endurance

Polyimide substrate with thickness of 10 μm were prepared using the above polyamic acid varnish. In the forming of the polyimide substrate, only the spin coating conditions was changed from the forming of the polyimide substrate described above. The polyimide substrate was cut into a shape of about 120 mm in length and 15 mm in width to obtain a test specimen. One end of this test specimen was set in MIT folding endurance tester (Type 307) manufactured by Yasuda Seiki Seisakusyo Ltd. and the other end was grasped and repeatedly folded, and the number of times of folding until breakage was measured. The measurement was carried out with folding radius of 0.38 mm, load of 0.5 kgf, folding angle of 270 degrees (135 degrees left and right), and folding speed of 175 times per minute. The measurement conditions are also shown below. At the time of the test, folding of the test specimen to one side was counted as one time. In addition, three specimens were tested, and the arithmetic mean of these test results, rounded to two digits of less, was used as the folding endurance measurement result. The upper limit number of the measurement result of the folding endurance was 1 million times. The measurement of the number of times of folding of the parylene film (Comparative Example 1-2) was similarly carried out. However, the measurement of the folding endurance of the glass substrate (Comparative Example 1-1) could not be carried out.

(Measurement Conditions)

folding radius: R=0.38 mm

Load: 0.5 kgf

folding angle: 270° (left and right 135°)

folding speed: 175 times per minute

Test times: n=3

d. Measurement of Glass Transition Temperature (Tg)

Polyimide substrate with thickness of 5 μm were prepared using the above polyamic acid varnish. In the forming of the polyimide substrate, only the spin coating conditions was changed from the forming of the polyimide substrate described above. The obtained polyimide substrate was cut into a width of 4 mm and a length of 20 mm. Glass transition temperature of the polyimide substrate was measured by a thermal analyzer (TMA-50) manufactured by Shimadzu Corporation. Measurement was similarly carried out on the parylene film (Comparative Example 1-2).

e. Measurement of Surface Roughness (Ra)

The surface roughness (Ra) of the above polyimide substrate, the inorganic glass plate (Comparative Example 1-1), and the parylene film (Comparative Example 1-2) were measured by AFM (NanoNavi IIs Nanocute manufactured by Seiko Instruments Inc.)

f. Film-Forming Property

The film-forming property of the polyimide substrate was evaluated by checking whether or not it had a smooth surface without unevenness due to aggregation or liquid repellency. When the surface was smooth, it was defined as “A”; when there was aggregation or liquid repellency, it was defined as “B”; when it was not evaluated, it was described as “-”.

g. Peelability

The peelability of the polyimide substrate from the peeling substrate (inorganic glass plate) in the laminated structure was evaluated as follows. First, a square notch was made with a scalpel along the four sides of the laminated structure (polyimide substrate laminated on the inorganic glass plate). Then, an adhesive tape was adhered along the outer edge of the polyimide substrate, the adhesive tape was grasped with a hand or tweezers, and the adhesive tape was pulled. When the polyimide substrate could be peeled off from the inorganic glass plate while maintaining the square shape as cut, it was defined as “A”; when the polyimide substrate could not be peeled off as desired, it was defined as B; when the evaluation was not performed, it was described as “-”.

TABLE 1

| | | | Maximum | | | | | | | |
|---|---|---|---|---|---|---|---|---|---|---|
| | | Transmittance | transmittance | | | | | | | |
| | | of light | of light | | | | | | | |
| | | having a | having a | | MIT | Glass | | Surface | | |
| | | wavelength | wavelength | | folding | transition | Thick- | roughness | Film- | |
| | | of 350 nm | of 400 ± 5 nm | b* | endurance | temperature | ness | Ra | forming | Peel- |
| | Sort | (%) | (%) | value | (times) | (° C.) | (μm) | (nm) | property | ability |
| Example 1 | polyimide | 4.5 | 79.2 | 2.2 | 85,000 | 268 | 1.3 | 1 | A | A |
| Comparative | glass | 90.4 | 92.0 | 0.0 | — | — | 700 | 0.5 | — | — |
| Example 1-1 | | | | | | | | | | |
| Comparative | parylene | 80 | 92 | 0.1 | <100 | <100 | 1 | 100 | — | — |
| Example 1-2 | | | | | | | | | | |

As shown in Table 1 above, in the polyimide substrate, although the transmittance of light having a wavelength of 350 nm was very low, the maximum transmittance of light having a wavelength of 400 nm±5 nm was 70% or more, and the b* value of the polyimide substrate was 5 or less. In other words, while the light transmittance in the visible region was excellent, the light transmittance in the ultraviolet region was low. Further, in the polyimide substrate, surface roughness was small, MIT folding endurance was excellent. Therefore, the polyimide substrate was proved to be excellent as substrate for flexible electronic devices. On the other hand, glass substrate or parylene film had high transmittance of light having a wavelength of 350 nm, indicating that it is difficult to suppress the ultraviolet light deterioration of the electronic element with these substrates alone.

2. Manufacturing of Organic Thin-Film Solar Cells

### Example 2

In the same manner as in the method for manufacturing the laminated structure described above, a fluorine-based resin layer was formed on the inorganic glass substrate (peeling substrate), and the polyimide substrate (thickness: 1.2 μm) was further formed. The physical properties of the obtained polyimide substrate are the same as the values shown in Table 1 described above.

An indium tin oxide (ITO) layer was formed on the polyimide substrate of the laminated structure by sputtering method. The thickness of the ITO layer (first electrode) was 100 nm. The obtained ITO layer was subjected to oxygen plasma treatment for 1 minute at an oxygen gas flow rate 5 sccm and the power of 300 W by PC300 manufactured by SAMCO Co., Ltd.

Subsequently, a solution obtained by dissolving 549 mg of zinc acetate dihydrate and 160 μl of ethanolamine in 5 ml of 2-methoxyethanol was added dropwise onto the ITO layer and spin-coated. The spin coating conditions were 5,000 rpm for 30 seconds. Thereafter, the laminate was heated to 70° C., further heated to 180° C. and held for 30 minutes, and cooled to room temperature to obtain a ZnO layer having a thickness of 30 nm.

Next, a solution of compound (PTzNTz-BOBO) having a structure represented by the following formula (7) and compound (PC71BM) having a structure represented by the following formula (8) dissolved in o-dichlorobenzene in a mass ratio of 1:2 was prepared. Then, the solution was heat-spin-coated on the ZnO layer (electron transport layer). The spin coating conditions were 100° C., 600 rpm, and 20 seconds. Thus, a photoelectric conversion layer with a thickness of 300-400 nm was obtained.

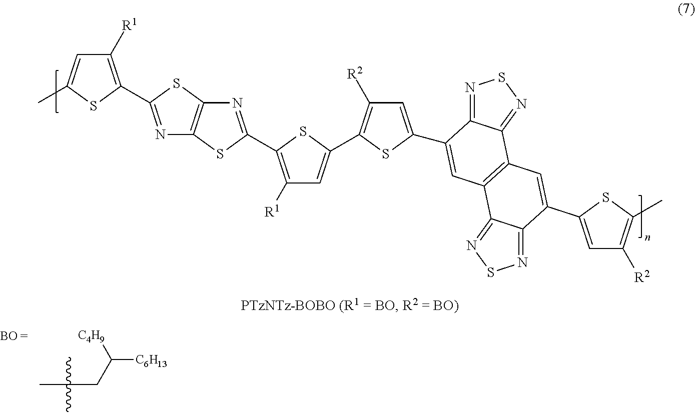

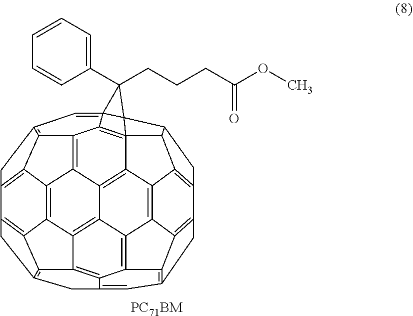

Subsequently, MoO₃ oxide layer (hole transporting layer) and Ag layer (second electrode) were formed on the photoelectric conversion layer by a vacuum evaporation method. Pressure at the time of layer forming was both less than 1×10⁻³ Pa. Further, the deposition rate of molybdenum oxide was 0.1 Å per second or less, and the deposition rate of silver was 1 Å per second or less. The thickness of MoO₃ layers was 7.5 nm, and the thickness of the Ag layers was 100 nm. Thereafter, an inorganic glass substrate (peeling substrate) and the fluorine-based resin layer were peeled off from the laminate to obtain an organic thin film solar cell.

### Comparative Example 2-1

A thin film solar cell was manufactured in the same manner as in Example 2, except that an inorganic glass substrate (alkali glass, thickness 0.7 mm) was used instead of the above-mentioned laminated structure, and each layer was formed on the inorganic glass substrate. The physical properties of the inorganic glass substrate are the same as the values shown in Table 1.

### Comparative Example 2-2

A thin film solar cell was manufacture in the same manner as in Example 2 except that an inorganic glass substrate was used and a UV bandpass filter (UTVAF-34U manufactured by Sigma Light Co., Ltd. (hereinafter also referred to as “UVP”)) was disposed on one side of the inorganic glass substrate and each layer was formed on the other side of the inorganic glass substrate.

### Comparative Example 2-3

An organic thin film solar cell was produced in the same manner as in Example 2 except that a parylene film (1 μm) laminated on a glass substrate and each layer was formed on the parylene film.

<Evaluation>

The flexibility and normalized photoelectric conversion efficiency (PCE) in the continuous drive test were measured for the thin film solar cells prepared in Example 2 and Comparative Examples 2-1 to 2-3. Evaluation results are shown in Table 2.

a. Flexibility

The thin film solar cells were folded to a radius of curvature of 1 mm. In this state, when the device performance is 90% or more, it was defined as “A”; when the device performance is less than 90%, it was defined as “B”.

b. Normalized Photoelectric Conversion Efficiency (PCE) in Continuous Drive Test

The thin film solar cells (active area 0.04 cm²) manufactured in Example 2 and Comparative Example 2-1 to 2-3 were irradiated with light under AM 1.5 G condition at intensity of 1,000 W/m² in a solar simulator at room temperature (22° C.) under atmospheric pressure, and the current-voltage characteristics were measured with a source meter 2400 manufactured by Keithley Instruments. At this time, the thin film solar cells were driven by imposing a control programmed to track the maximum power at all times (Maximum Power Point Tracking) and the normalized photoelectric conversion efficiency (PCE) was determined from the current-voltage curve.

TABLE 2

| | | | MPPT | | |
|---|---|---|---|---|---|
| | | | Initial | 180 minutes | PCE reduction |
| | | Flexibility of | PCE | later PCE | suppression rate |
| | Substrate | Device | (%) | (%) | (180 minites/Initial) |
| Example 2 | polyimide | A | 9.0 | 8.1 | 0.90 |
| Comparative | glass | B | 9.3 | 3.4 | 0.37 |
| Example 2-1 | | | | | |
| Comparative | glass and | B | 7.3 | 6.2 | 0.85 |
| Example 2-2 | UVP | | | | |
| Comparative | glass and | A | 7.2 | 4 | 0.56 |
| Example 2-3 | parylene | (when using | | | |
| | | parylene only) | | | |

As shown in Tables 1 and 2 above, when the polyimide substrate (the substrate having the same physical properties as Example 1 in Table 1) in which the transmittance of light having a wavelength of 350 nm was 10% or less, the maximal transmittance of light having a wavelength of 400±5 nm was 70% or more, and the b* value of L*a*b* colorimetric system was 5 or less was used (Example 2), the PCE reduction suppression rate was very high. By using the polyimide substrate, deterioration of the solar cell element due to irradiation with ultraviolet light can be suppressed. Further, when the polyimide substrate was used, the initial PCE was sufficiently high. That is, according to the device substrate of the present application, it was possible to suppress the ultraviolet light deterioration while maintaining the high photoelectric conversion efficiency.

On the other hand, in the case of using the glass substrate (Comparative Example 2-1) or the case of using parylene (Comparative Example 2-3), the PCE reduction suppression rate was low and the solar cell element was prone to be deteriorated. When the glass substrate and the UV bandpass filter (UVP) were used (Comparative Example 2-2) as the substrate, the initial PCE was lower than that of the polyimide substrate, and the PCE reduction suppression rate was also lower than that of the polyimide substrate.

This application claims priority to Patent Application No. 2018-145648, filed Aug. 2, 2018. All of the contents set forth in the specification of the application are incorporated herein by reference.

### INDUSTRIAL APPLICABILITY

The substrate for a flexible electronic device of the present invention includes a polyimide layer having both low ultraviolet light transmittance and high visible light transmittance, and capable of suppressing ultraviolet deterioration without decreasing the performance of the electronic device. Therefore, it is very useful as a substrate for various flexible electronic devices. With the laminated structure of the present invention, the polyimide substrate suitable for a flexible electronic device can be easily peeled off. Therefore, it is useful for the manufacturing of various flexible electronic devices.

1. A substrate for a flexible electronic device comprising a polyimide layer, wherein the polyimide layer comprises following characteristics (1) to (3):
(1) when the polyimide layer has a thickness of 5 μm, a maximum transmittance of light having a wavelength of 400±5 nm is 70% or more;
(2) when the polyimide layer has a thickness of 5 μm, b* value of a L*a*b* colorimetric system is 5 or less; and
(3) when the polyimide layer has a thickness of 5 μm, a transmittance of light having a wavelength of 350 nm is 10% or less.

2. The substrate for a flexible electronic device according to claim 1, wherein the polyimide layer further comprises following characteristics (4) to (7):
(4) when the polyimide layer has a thickness of 10 μm, a number of times of folding measured according to JIS P8115 in an MIT folding endurance test is 10,000 or more;
(5) a glass transition temperature is 200° C. or higher;
(6) a thickness is 10 μm or less; and
(7) at least one surface has a surface roughness (Ra) of 5 nm or less.

3. The substrate for a flexible electronic device according to claim 1, wherein the substrate further comprises a base material.

4. The substrate for a flexible electronic device according to claim 1, wherein the polyimide layer comprises a polyimide having a repeating structural unit represented by a following general formula (1) or a following general formula (2): 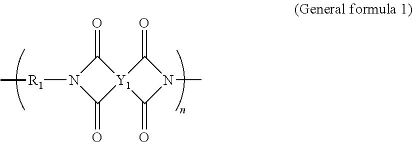
wherein in the general formula (1),
R₁ is a divalent group having 4 to 15 carbon atoms including one or more alicyclic hydrocarbon structure(s) or a divalent linear aliphatic group having 5 to 12 carbon atoms, and Y₁ is a tetravalent group having 6 to 27 carbon atoms including aromatic ring or rings: 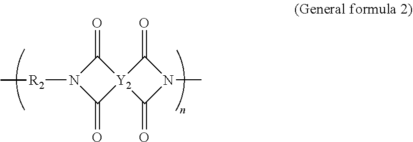
wherein in the general formula (2),
R₂ is a divalent group having 6 to 27 carbon atoms including one or more aromatic ring(s), and Y₂ is a tetravalent group having 4 to 12 carbon atoms including one or more alicyclic hydrocarbon(s).

5. The substrate for a flexible electronic device according to claim 4, wherein R₁ of the repeating structural unit represented by the general formula (1) is at least one divalent group selected from the group consisting of
—CH₂—CH₂—CH₂—CH₂—CH₂—,
—CH₂—CH₂—CH₂—CH₂—CH₂—CH₂—,
—CH₂—CH₂—CH₂—CH₂—CH₂—CH₂—CH₂—, 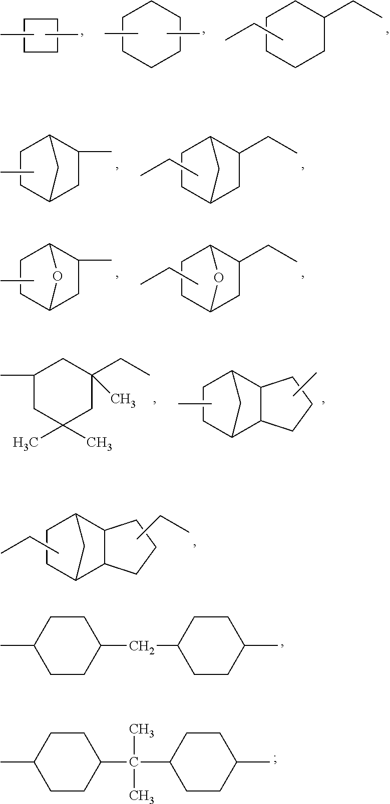
wherein Y₁ of the repeating structural unit represented by the general formula (1) is at least one tetravalent group selected from the group consisting of 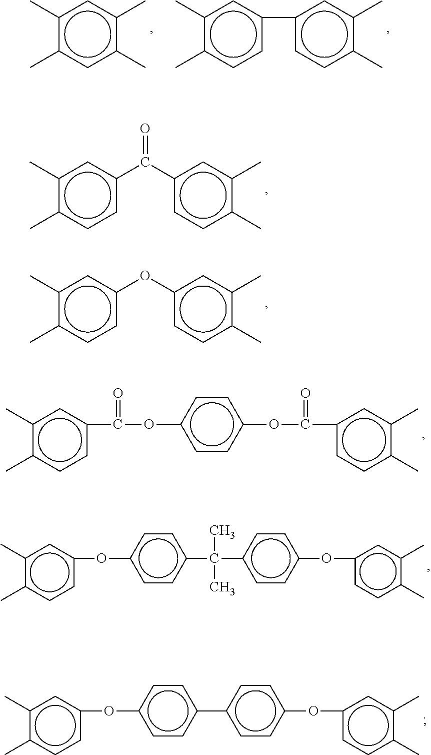
wherein R₂ of the repeating structural unit represented by the general formula (2) is at least one divalent group selected from the group consisting of 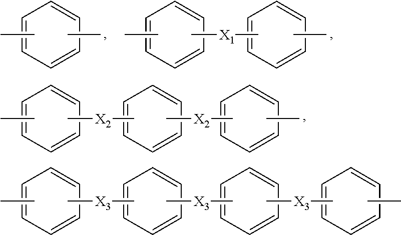
in the above formulae, X₁˜X₃ are each independently a single bond or a divalent group selected from the group consisting of 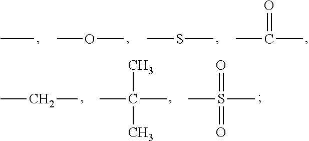
wherein Y₂ of the repeating structural unit represented by the general formula (2) is at least one tetravalent group selected from the group consisting of

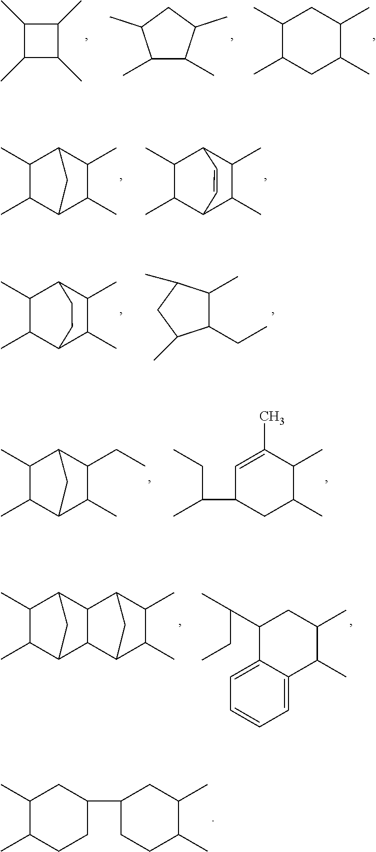

6. An organic thin film solar cell, wherein the substrate for a flexible electronic element according to claim 1, a first electrode, a photoelectric conversion layer, and a second electrode are stacked in this order.

7. A laminated structure, comprising:
a peeling substrate;
a fluorine-based resin layer having a contact angle of 13° or more and 85° or less with water, the fluorine-based resin layer being disposed on the peeling substrate; and
a polyimide substrate disposed adjacent to the fluorine-based resin layer,
wherein, when the polyimide substrate has a thickness of 5 μm, a transmittance of light having a wavelength of 350 nm of the polyimide substrate is 10% or less.

8. The laminated structure according to claim 7, wherein the polyimide substrate comprises a polyimide having a repeating structural unit represented by a following general formula (3) or a following general formula (4): 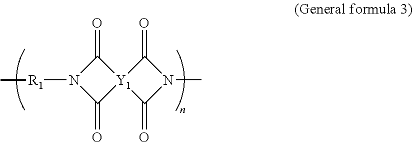
wherein, in the general formula (3),
R₁ is a divalent group having 4 to 15 carbon atoms including one or more alicyclic hydrocarbon structure(s) or a divalent linear aliphatic group having 5 to 12 carbon atoms, and Y₁ is a tetravalent group having 6 to 27 carbon atoms including one or more aromatic ring(s): 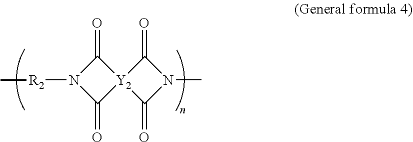
wherein in the general formula (4),
R₂ is a divalent group having 6 to 27 carbon atoms including one or more aromatic ring(s), and Y₂ is a tetravalent group having 4 to 12 carbon atoms including alicyclic hydrocarbon structure or structures.

9. The laminated structure according to claim 8, wherein R₁ of the repeating structural unit represented by the general formula (3) is at least one divalent group selected from the group consisting of
—CH₂—CH₂—CH₂—CH₂—CH₂—,
—CH₂—CH₂—CH₂—CH₂—CH₂—CH₂—,
—CH₂—CH₂—CH₂—CH₂—CH₂—CH₂—CH₂—, 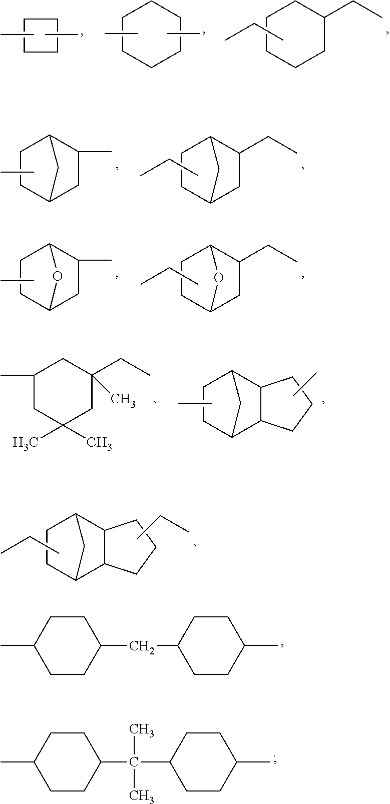
wherein Y₁ of the repeating structural unit represented by the general formula (3) is at least one tetravalent group selected from the group consisting of 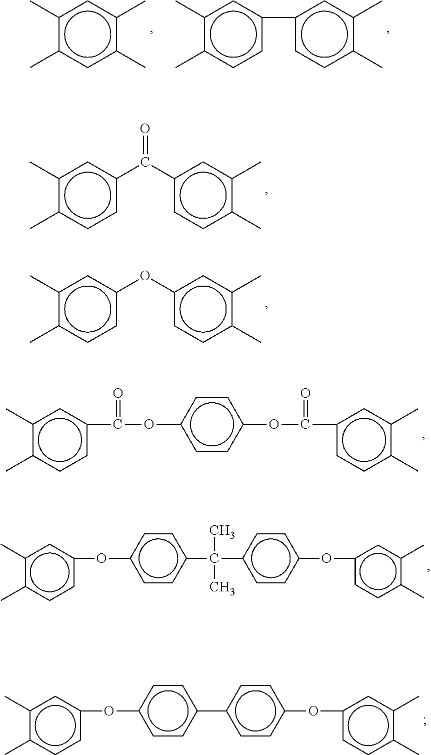
wherein R₂ of the repeating structural unit represented by the general formula (4) is at least one divalent group selected from the group consisting of 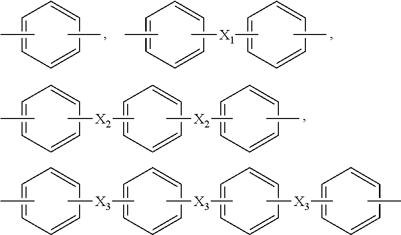
in the above formulae, X₁˜X₃ are each independently a single bond or a divalent group selected from the group consisting of 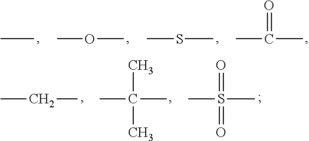
wherein Y₂ of the repeating structural unit represented by the general formula (4) is at least one tetravalent group selected from the group consisting of

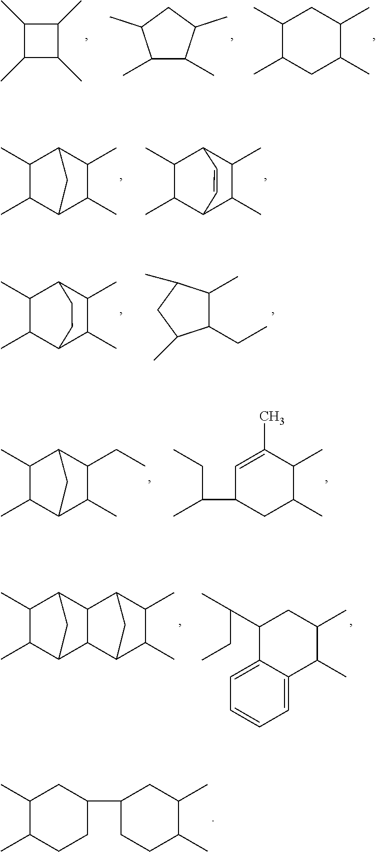

10. A method for manufacturing the laminated structure according to claim 7, comprising:
forming the fluorine-based resin layer on the peeling substrate; and
forming the polyimide substrate on the fluorine-based resin layer;
wherein the fluorine-based resin layer has a contact angle of 13° or more and 85° or less with water on a surface of the fluorine-based resin layer.

11. A method for manufacturing a flexible electronic device, comprising:
forming an electronic element on the polyimide substrate of the laminated structure according to claim 7; and
peeling off the fluorine-based resin layer and the peeling substrate from the polyimide substrate after the forming of the electronic element.
